(19) United States
(12) Patent Application Publication
(10) Pub. No.: US 2026/0352005 A1
(43) Pub. Date: Nov. 5, 2026

(54) BACKGROUND CALIBRATION FOR CURRENT SENSING OF POWER FIELD EFFECT TRANSISTOR FOR BATTERY MANAGEMENT SYSTEM

(71) Applicant: Cirrus Logic International Semiconductor Ltd., Edinburgh (GB)

(72) Inventors: Rohit BUPATHY SUDAN, Austin, TX (US); Paul WILSON, Edinburgh (GB)

(73) Assignee: Cirrus Logic International Semiconductor Ltd., Edinburgh (GB)

(21) Appl. No.: 19/197,169

(22) Filed: May 2, 2025

(51) Int. Cl. H02J 7/80; G01R 31/26; G01R 35/00

(52) U.S. Cl. CPC H02J 7/80; G01R 31/2625; G01R 35/005

(57) ABSTRACT

A system may include a first FET, a second FET which is a scaled replica of the first FET, and is electrically coupled to the first FET such that a first current flowing through the first FET is proportional to a second current flowing through the second FET. The system may also include a test current generation circuit configured to generate a first test signal into the first FET and generate a second test signal into the second FET. The system may further include a controller configured to determine a gain error between the first FET and the second FET based on respective results of the first test signal into the first FET and the second test signal into the second FET and use the gain error to apply a correction for sensing of the first current based on sensing of the second current.

### FIELD OF DISCLOSURE

The present disclosure relates in general to circuits for electronic devices, including without limitation personal audio devices such as wireless telephones and media players, and more specifically, systems and methods for background calibration for current sensing of a power field-effect transistor (FET) of a battery management system.

### BACKGROUND

Portable electronic devices, including wireless telephones, such as mobile/cellular telephones, tablets, cordless telephones, mp3 players, smart watches, health monitors, and other consumer devices, are in widespread use. Such a portable electronic device may include a battery (e.g., a lithium-ion battery) for powering components of the portable electronic device. Typically, such batteries used in portable electronic devices are rechargeable, such that when charging, the battery converts electrical energy into chemical energy which may later be converted back into electrical energy for powering components of the portable electronic device.

Such devices may include a battery management system, which may be implemented as a battery management integrated circuit (IC), for fuel gauging of a battery, battery charging of the battery, and/or power delivery to/from the battery. Oftentimes, for battery charging and power delivery applications, there is a need for precise current sensing of power flowing through a power FET of the battery management system. A power FET may be controlled within the battery management system to selectively couple/decouple a battery from a power source, as well as control current and/or voltage to the battery.

In many battery management systems, current through a power FET is typically measured using a sense FET, which is a replica of the power FET and is electrically coupled to the power FET in a manner such that, in ideal conditions, the current through the sense FET is proportional to the current through the power FET. However, current sensing accuracy in such systems may be limited by mismatch between the power FET and the sense FET, including factors such as metal routing mismatch between the power FET and the sense FET, Kelvin sense point errors between the power FET and the sense FET, inaccuracy of extraction of parasitic effects by simulation and characterization tools, placement of solder balls on a circuit board, solder ball current density, circuit board layout, mechanical induced electrical stress, and mismatch within high-voltage power FETs.

Accordingly, systems and methods for determining and correcting for any such mismatch may be desirable.

### SUMMARY

In accordance with the teachings of the present disclosure, one or more disadvantages and problems associated with existing approaches to sensing of current through a power FET in a battery management system may be reduced or eliminated.

In accordance with embodiments of the present disclosure, a system may include a first FET, a second FET which is a scaled replica of the first FET, and is electrically coupled to the first FET such that a first current flowing through the first FET is proportional to a second current flowing through the second FET. The system may also include a test current generation circuit configured to generate a first test signal into the first FET and generate a second test signal into the second FET. The system may further include a controller configured to determine a gain error between the first FET and the second FET based on respective results of the first test signal into the first FET and the second test signal into the second FET and use the gain error to apply a correction for sensing of the first current based on sensing of the second current.

In accordance with these and other embodiments of the present disclosure, a method may include generating a first test signal into a first FET, generating a second test signal into a second FET, determining a gain error between the first FET and the second FET based on respective results of the first test signal into the first FET and the second test signal into the second FET, and using the gain error to apply a correction for sensing of the first current based on sensing of the second current.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates an example system for charging a battery, in accordance with embodiments of the present disclosure;

FIG. 2 illustrates selected components of a battery management system, in accordance with embodiments of the present disclosure; and

FIG. 3 illustrates example waveforms of various signals of the battery management system during a background calibration procedure, in accordance with embodiments of the present disclosure.

### DETAILED DESCRIPTION

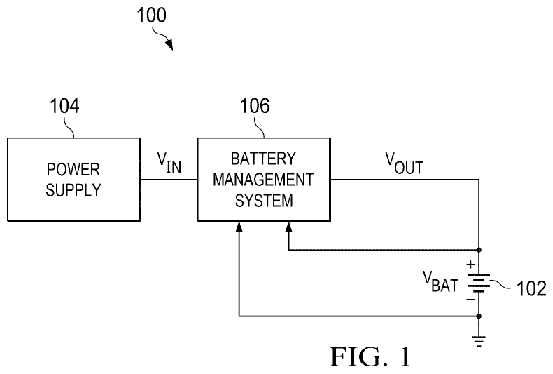

FIG. 1 illustrates an example system 100 for charging a battery 102, in accordance with embodiments of the present disclosure. As shown in FIG. 1, system 100 may include battery 102, a power supply 104, and a battery management system 106.

Battery 102 may include any system, device, or apparatus configured to convert chemical energy stored within battery 102 to electrical energy. For example, in some embodiments, battery 102 may be integral to a portable electronic device, and battery 102 may be configured to deliver electrical energy to components of such portable electronic device. Further, battery 102 may also be configured to recharge, in which it may convert electrical energy received by battery 102 into chemical energy to be stored for later conversion back into electrical energy. As an example, in some embodiments, battery 102 may comprise a lithium-ion battery.

Power supply 104 may include any system, device, or apparatus configured to supply electrical energy to battery management system 106. In some embodiments, power supply 104 may include a direct-current (DC) power source configured to deliver electrical energy at a substantially constant voltage. Accordingly, a peak-to-average power delivered from power supply 104 may be approximately equal to 1. In some of such embodiments, power supply 104 may include an alternating current (AC)-to-DC converter/adapter, configured to convert an AC voltage (e.g., provided by an electrical socket installed in the wall of a building) into a DC voltage.

Battery management system 106 may include any system, device, or apparatus configured to receive electrical energy from power supply 104 and/or battery 102, and control delivery of such energy to and/or from battery 102. In some embodiments, battery management system 106 may comprise a battery charger, configured to deliver electrical energy to battery 102 in order that battery 102 converts the electrical energy to chemical energy that is stored in battery 102. In some embodiments, battery management system 106 may include a wired charger configured to draw electrical energy from an electrical power outlet or from a power bank. In other embodiments, battery management system 106 may include a wireless charger configured to draw electrical energy via inductive coupling from a wireless charging pad or similar device. Battery management system 106 may be used for fuel gauging of a battery, charging of the battery, and/or power delivery to/from the battery.

In operation, battery management system 106 may monitor operating parameters associated with battery 102, including without limitation a current flowing to battery 102, voltages associated with battery 102, and/or other parameters, to control and/or monitor operation of battery 102.

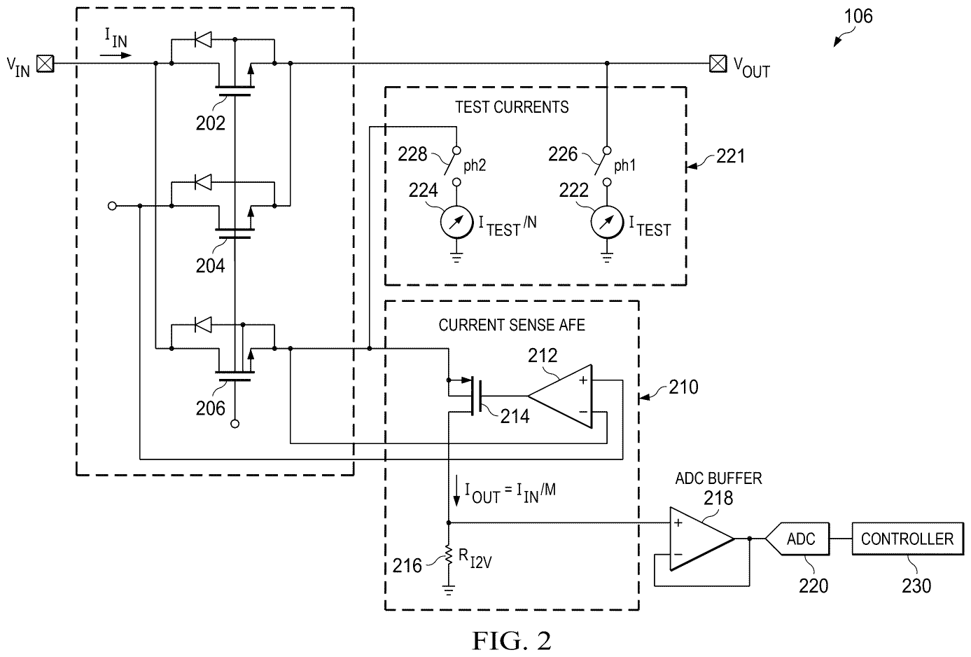

FIG. 2 illustrates selected components of a battery management system 106, in accordance with embodiments of the present disclosure. As shown in FIG. 2, battery management system 106 may include a power FET 202, one or more replica FETs 204 and 206, a current sense analog front end (AFE) 210, an analog-to-digital converter (ADC) buffer 218, an ADC 220, a test current generation circuit 221, and a controller 230.

Power FET 202 may include any suitable transistor that may be controlled (e.g., by controller 230), to selectively couple/decouple power supply 104 to/from battery 102, and/or controlled to generate an accurate current/voltage to/from battery 102.

Replica FETs 204, 206 may each include any suitable transistor electrically coupled to power FET 202 in such a manner that a current flowing through each of replica FETs 204, 206 is proportional to input current I_{IN} flowing through power FET 202, assuming absence of mismatches between power FET 202 and replica FETs 204, 206. Replica FETs 204 and 206 may be, in many respects, identical to power FET 202 except that in some embodiments, power FET 202 and replica FETs 204, 206 may be sized such that an impedance of each of replica FETs, 204, 206 may be a multiplicative factor greater than an impedance of power FET 202, wherein such multiplicative factor may be referred to as a sense ratio M.

Current sense AFE 210 may comprise any suitable circuit for sensing input current from replica FETs 204, 206. For example, as shown in FIG. 2, current sense AFE 210 may include an operational amplifier 212 configured having its positive input terminal coupled to a source terminal of replica FET 204, having its negative input terminal coupled to a drain terminal of replica FET 206, and having its output terminal driving a gate terminal of a PFET source follower 214. PFET source follower 214 may be (via its source and drain terminals) coupled between a drain terminal of replica FET 206 and a sense resistor 216, wherein one terminal of sense resistor 216 is coupled to ground and has a resistance R_{I2V}. In operation, current sense AFE 210 may implement a force and sense-based feedback loop in which current sense AFE 210 may attempt to force the respective source and drain voltages of power FET 202 and replica FETs 204, 206 to be very close in magnitude to each other. Accordingly, an output current I_{OUT} flowing through PFET source follower 214 may be equal to I_{OUT}=I_{IN}/M. Such output current I_{OUT} may then flow through sense resistor 216, converting output current I_{OUT} to a voltage equal to the product of output current I_{OUT} and resistance R_{I2V}, which such voltage may be buffered by ADC buffer 218 and converted to an equivalent digital signal by ADC 220.

Test current generation circuit 221 may include any suitable system, device, or apparatus configured to generate test current signals during a background calibration procedure of battery management system 106, as described in greater detail below. While test current generation circuit 221 may take many forms, in some embodiments, test current generation circuit 221 may include a first test current source 222, a second test current source 224, a first phase test switch 226, and a second phase test switch 228, as shown in FIG. 2.

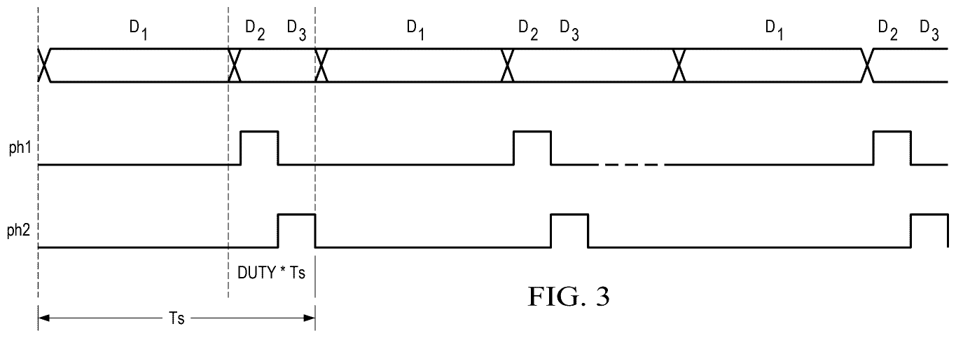

As mentioned in the Background section, current sensing accuracy may be limited by mismatch between power FET 202 and replica FETs 204, 206, such that the ratio of respective currents through each vary from the sense ratio M. This variance may be a multiplicative factor referred to as a gain error α. During a first phase ph1 of the background calibration procedure, test current generation circuit 221 may inject a known test current I_{TEST} into power FET 202 to generate a digital signal D₂ from ADC 220 indicative of output current I_{OUT} through sense resistor 216 which has a term that includes gain error α. During a second phase ph2 of the background calibration procedure, test current generation circuit 221 may inject a scaled-down version of known test current I_{TEST} (e.g., I_{TEST}/N, where N may be 20 or any other suitable multiplicative factor) directly into sense resistor 216 to generate a digital signal D₃ from ADC 220 indicative of output current I_{OUT} through sense resistor 216 which has a term excluding gain error α. Accordingly, a division of the terms from digital signal D2 and digital signal D3 (e.g., by controller 230) may provide the actual replica ratio (i.e., the product α·M) between power FET 202 and replica FETs 204, 206, which may be used to calibrate current measurement as a function of gain error α. The background calibration procedure may be further understood by reference to FIG. 3, discussed below.

Controller 230 may comprise any suitable system, device, or apparatus configured to control components of battery management system 106 (e.g., including without limitation power FET 202, replica FETs 204, 206, and test current generation circuit 221), including controlling one or more of such components to implement the background calibration procedure discussed above and below.

FIG. 3 illustrates example waveforms of various signals of battery management system 106 during a background calibration procedure, in accordance with embodiments of the present disclosure. As shown in FIG. 3, when in normal operation (e.g., not operating in the background calibration procedure), the current-sensing components of battery management system 106 may cause ADC 220 to generate digital signal D₁ indicative of output current I_{OUT} through sense resistor 216, wherein:

$${D}_{1} = \frac{{I}_{IN}}{α \cdot M} {R}_{I 2 V}$$

In first phase ph1 of the background calibration procedure, test current generation circuit 221 may inject test current I_{TEST} into power FET 202 to generate digital signal D₂:

$${D}_{2} = \frac{{I}_{IN} + {I}_{TEST}}{α \cdot M} {R}_{I 2 V}$$

In second phase ph2 of the background calibration procedure, test current generation circuit 221 may inject a scaled-down version of known test current I_{TEST}, I_{TEST}/N directly into sense resistor 216 to generate a digital signal D₃:

$${D}_{3} = ( \frac{{I}_{IN}}{α \cdot M} + \frac{{I}_{TEST}}{N} ) {R}_{I 2 V}$$

From digital signals D₂ and D₃, controller 230 may use mathematical operations to solve for the actual replica ratio α·M. Knowing the actual replica ratio, controller 230 may then apply a proper calibration to measurements of digital signal D₁ in order to generate accurate measurements of input current I_{IN}. In some embodiments, such calibration or correction may be performed digitally. In other embodiments, such calibration or correction may be performed in the analog domain.

As disclosed herein, embodiments of the present disclosure may involve a calibration scheme that provides the accuracy for determining the thresholds for activating or deactivating the power FET(s) based on a particular type of detected fault condition. Two independent sources for measuring current may be utilized. One independent source is an analog-to-digital converter (ADC) that measures current across a power FET. Another independent source is an ADC (maybe the same or another ADC) that measures across a low-side resistor. The calibration scheme may be performed one time during manufacturing calibration or during power up of a battery management system, such as a battery management IC. A scale factor may be determined from the readings of the ADC(s) (e.g., to make an estimation of an on resistance of the power FET accurately at room temperature). Different scale factors may be used depending on the operating mode of the power FET(s). When a fault is detected, the power FET(s) may be deactivated (i.e., the battery is not able to charge or discharge). Advantageously, a high-side precision resistor may not be needed in this scheme.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A system comprising:
a first field-effect transistor (FET);
a second FET which is a scaled replica of the first FET, and is electrically coupled to the first FET such that a first current flowing through the first FET is proportional to a second current flowing through the second FET;
a test current generation circuit configured to:
generate a first test signal into the first FET; and
generate a second test signal into the second FET; and
a controller configured to:
determine a gain error between the first FET and the second FET based on respective results of the first test signal into the first FET and the second test signal into the second FET; and
use the gain error to apply a correction for sensing of the first current based on sensing of the second current.

2. The system of claim 1, wherein the controller is configured to apply such correction digitally.

3. The system of claim 1, wherein the correction is an analog correction.

4. The system of claim 1, wherein the first FET is a power FET coupled between a power source and a battery and configured to control flow of electrical energy between the power source and the battery.

5. The system of claim 1, wherein the gain error is due to one or more mismatches between the first FET and the second FET.

6. The system of claim 1, wherein the first test signal is a first current and the second test signal is a second current.

7. The system of claim 1, wherein the test generation circuit is further configured to generate the first test signal into the first FET and generate the second test signal into the second FET during a background calibration procedure.

8. The system of claim 7, wherein the test generation circuit is further configured to:
generate the first test signal into the first FET during a first phase of the background calibration procedure; and
generate the second test signal into the second FET during a second phase of the background calibration procedure.

9. A method comprising:
generating a first test signal into a first field-effect transistor (FET); and
generating a second test signal into a second FET;
determining a gain error between the first FET and the second FET based on respective results of the first test signal into the first FET and the second test signal into the second FET; and
using the gain error to apply a correction for sensing of the first current based on sensing of the second current.

10. The method of claim 9, wherein the correction is a digital correction.

11. The method of claim 9, wherein the correction is an analog correction.

12. The method of claim 9, wherein the first FET is a power FET coupled between a power source and a battery and configured to control flow of electrical energy between the power source and the battery.

13. The method of claim 9, wherein the gain error is due to one or more mismatches between the first FET and the second FET.

14. The method of claim 9, wherein the first test signal is a first current and the second test signal is a second current.

15. The method of claim 9, further comprising generating the first test signal into the first FET and generating the second test signal into the second FET during a background calibration procedure.

16. The system of claim 15, further comprising:
generating the first test signal into the first FET during a first phase of the background calibration procedure; and
generating the second test signal into the second FET during a second phase of the background calibration procedure.
